(19) United States
(12) Patent Application Publication
(10) Pub. No.: US 2009/0241837 A1
(43) Pub. Date: Oct. 1, 2009

(54) CERAMIC MEMBER, CERAMIC HEATER, SUBSTRATE PLACING MECHANISM, SUBSTRATE PROCESSING APPARATUS AND METHOD FOR MANUFACTURING CERAMIC MEMBER

(75) Inventor: Yoshiyuki Hanada, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 12/064,908

(22) PCT Filed: Aug. 23, 2006
(86) PCT No.: PCT/JP2006/316452

§ 371 Date: Feb. 26, 2008

(30) Foreign Application Priority Data
Aug. 26, 2005 (JP) 2005-246786

(51) Int. Cl. C23C 16/00; C04B 35/645; C04B 35/64; H05B 3/10

(52) U.S. Cl. 118/725; 501/94; 118/728; 264/603; 219/548

(57) ABSTRACT

A wafer mounting table constituted as a ceramic heater has a power feeding terminal section for a heating element and a bonding section to a supporting member as portions which are likely to be crack starting points. The wafer mounting table is constituted to permit compressive stress to be generated in the power feeding terminal section and/or the bonding section which are likely to be the crack starting points.

### FIELD OF THE INVENTION

The present invention relates to a ceramic member and a ceramic heater, both for use in mounting a substrate thereon for example, a substrate mounting mechanism employing the both, a substrate processing apparatus, such as a film forming apparatus or the like, including the substrate mounting mechanism and a method for manufacturing the ceramic member.

### BACKGROUND OF THE INVENTION

In a semiconductor device manufacturing process, a semiconductor wafer as a target substrate is subjected to a vacuum processing such as a CVD film forming process or a plasma etching process. The vacuum processing requires a heat treatment for heating the semiconductor wafer as the target substrate to a specific temperature. Accordingly, the semiconductor wafer is heated by a heater serving as a substrate mounting table.

As for the heater, a stainless steel heater or the like has been conventionally used. However, a ceramic heater is recently proposed due to its high thermal efficiency and corrosion resistance to a halogen-based gas used in the aforementioned processing (see, Japanese Patent Laid-open Application No. H7-272834). Such a ceramic heater includes a base body serving as a mounting table for mounting thereon a target substrate and a heating element buried in the base body. The base body is made of a dense sintered ceramic, e.g., AlN or the like, and the heating element is formed of a refractory metal.

When a substrate mounting table configured as the ceramic heater is installed in a substrate processing apparatus, one end of a cylindrical supporting member made of a ceramic material is connected to a backside of the substrate mounting table and the other end thereof is connected with a bottom portion of a chamber. The supporting member has therein power feed lines for supplying power to the heating element, and the power feed lines are connected with terminals of the heating element. Thus, the power can be supplied from an external power supply to the heating element via the power feed lines and the power feed terminals.

Meanwhile, the heat is often lost at a bonding section between the supporting member and the substrate mounting table configured as the ceramic heater through the supporting member and the power feed lines. As a consequence, the bonding section has a lower temperature compared with other portions, so that a tensile stress derived from a thermal expansion difference is applied thereto. Since the bonding section, the power feed terminals and the like are likely to be crack starting points in structure, the application of the tensile stress to those portions results in a breakage of the ceramic heater.

### SUMMARY OF THE INVENTION

The present invention provides a ceramic member that is hardly broken despite the presence of portions that may be crack starting points, a ceramic heater of the ceramic member, a substrate mounting mechanism using the ceramic member and the ceramic heater, a substrate processing apparatus including the substrate mounting mechanism and a method for manufacturing the ceramic member.

In accordance with a first aspect of the invention, there is provided a ceramic member having a portion that is likely to be a crack starting point, wherein a compressive stress is generated in the portion that is likely to be the crack starting point.

In accordance with a second aspect of the invention, there is provided a ceramic heater including: a main body formed of a ceramic member; a heating element buried in the main body; and a power feeding section where power is supplied to the heating element, wherein a compressive stress is applied to the vicinity of the power feeding section of the main body.

In accordance with a third aspect of the invention, there is provided a substrate mounting mechanism for mounting a substrate in a processing chamber of a substrate processing apparatus, the substrate mounting mechanism including: a substrate mounting table formed of a ceramic member, for mounting thereon a substrate; and a supporting member having one end connected to the substrate mounting table, for supporting the substrate mounting table in the processing chamber, wherein a compressive stress is applied to a section of the ceramic member to which the supporting member is connected.

In accordance with a fourth aspect of the invention, there is provided a substrate mounting mechanism for mounting a substrate in a processing chamber of a substrate processing apparatus, the substrate mounting mechanism including: a substrate mounting table formed of a ceramic member, for mounting thereon a substrate; and a supporting member for supporting the substrate mounting table in the processing chamber, wherein the substrate mounting table has a plurality of through holes through which a plurality of substrate supporting pins for supporting the substrate is inserted, and a compressive stress is applied to portions where the through holes of the substrate mounting table are provided.

In accordance with a fifth aspect of the invention, there is provided a substrate mounting mechanism for mounting and heating a substrate in a processing chamber of a substrate processing apparatus, the substrate mounting mechanism including: a substrate mounting table formed of a ceramic member, for mounting thereon a substrate, the substrate mounting table having a base body and a heating element buried in the base body to heat the substrate; a supporting member having one end connected to the substrate mounting table, for supporting the substrate mounting table in the processing chamber; and a power feeding section where power is supplied to the heating element via power feed lines extending through the supporting member, wherein a compressive stress is generated in a section of the substrate mounting table to which the power feeding section and/or the supporting member are/is connected.

In accordance with a sixth aspect of the invention, there is provided a substrate processing apparatus including: a processing chamber having an inner space maintained at a depressurized state, for accommodating therein a substrate; a substrate mounting mechanism provided in the processing chamber, for mounting the substrate; and processing mechanism for performing a specific processing on the substrate in the processing chamber, wherein the substrate mounting mechanism includes: a substrate mounting table formed of a ceramic member, for mounting thereon a substrate; and a supporting member having one end connected to the substrate mounting table, for supporting the substrate mounting table in the processing chamber, wherein a compressive stress is applied to a section of the ceramic member to which the supporting member is connected.

In accordance with a seventh aspect of the invention, there is provided a substrate processing apparatus including: a processing chamber having an inner space maintained at a depressurized state, for accommodating therein a substrate; a substrate mounting mechanism provided in the processing chamber, for mounting the substrate; and a processing mechanism for performing a specific processing on the substrate in the processing chamber, wherein the substrate mounting mechanism includes: a substrate mounting table formed of a ceramic member, for mounting thereon a substrate; and a supporting member for supporting the substrate mounting table in the processing chamber, wherein the substrate mounting table has a plurality of through holes through which a plurality of substrate supporting pins for supporting the substrate is inserted, wherein a compressive stress is applied to portions where the through holes of the substrate mounting table are provided.

In accordance with an eighth aspect of the invention, there is provided a substrate processing apparatus including: a processing chamber having an inner space maintained at a depressurized state, for accommodating therein a substrate; a substrate mounting mechanism provided in the processing chamber, for mounting the substrate; and a processing mechanism for performing a specific processing on the substrate in the processing chamber, wherein the substrate mounting mechanism includes: a substrate mounting table formed of a ceramic member, for mounting thereon a substrate, the substrate mounting table having a base body and a heating element buried in the base body to heat the substrate; a supporting member having one end connected to the substrate mounting table, for supporting the substrate mounting table in the processing chamber; and a power feeding section where power is supplied to the heating element via power feed lines extending through the supporting member, wherein a compressive stress is generated in a section of the substrate mounting table to which the power feeding section and/or the supporting member are/is connected.

In accordance with a ninth aspect of the invention, there is provided a method for manufacturing a ceramic member including: generating a compressive stress in a portion of the ceramic member that is likely to be a crack starting point during a manufacturing process of the ceramic member.

In accordance with the third, the fifth, the sixth and the eighth aspect of the invention, there can be employed a configuration in which the supporting member is provided at a central portion of the substrate mounting table.

In accordance with the ninth aspect of the invention, the compressive stress may be generated by sintering a portion that is likely to be a crack starting points and the other portion at different temperatures. The compressive stress may also be generated by sintering the portion that is likely to be a crack starting point and the other portions while differentiating at least one of type, quantity and composition of an additive there between. In addition, the compressive stress may be generated due to a thermal expansion difference between the ceramic member and an annular tension generating element provided at a peripheral portion or an outer circumferential portion of the ceramic member.

The ceramic member of the present invention is generally an inorganic sintered body. However, it can also be, without being limited thereto, a member made of a variety of ceramic materials including glass, e.g., quartz glass or the like, a single crystalline material and the like.

In accordance with the present invention, the portion having crack starting points is hardly broken by generating the compressive stress thereto. To be specific, the compressive stress is generated in the portions that can be crack starting points, e.g. the bonding section between the supporting member and the substrate mounting table configured as the ceramic heater and/or the power feeding section for supplying power to the heating element via the power feed lines extending through the supporting member, to thereby prevent the breakage of those portions.

### BRIEF DESCRIPTION OF THE DRAWINGS

FIG. 1 is a schematic cross sectional view of a CVD film forming apparatus employing a wafer mounting table in accordance with an embodiment of the present invention.

FIG. 2 illustrates an enlarged cross sectional view of the wafer mounting mechanism in accordance with the embodiment of the present invention.

FIG. 3 describes a stress distribution in a diametrical direction of the wafer mounting table in accordance with the embodiment of the present invention.

FIG. 4 provides a graph depicting a relationship between a sintering temperature and a shrinkage rate of AlN.

FIG. 5 shows a schematic diagram of a hot pressing device capable of sintering a central portion and a peripheral portion of a ceramic member at different temperatures.

FIG. 6 presents a relationship, in case of using a sintering aid, between a sintering temperature and a shrinkage rate of AlN.

FIG. 7A explains a process for providing a partition member in a method for differentiating at least one of type, quantity and composition of an additive (sintering aid) between the central portion and the peripheral portion;

FIG. 7B shows a process for inputting source materials in the method for differentiating at least one of type, quantity and composition of an additive (sintering aid) between the central portion and the peripheral portion;

FIG. 7C presents a process for separating the partition member in the method for differentiating at least one of type, quantity and composition of an additive (sintering aid) between the central portion and the peripheral portion;

FIG. 8A shows a case where a plurality of layers are provided in a thickness direction while differentiating at least one of type, quantity and composition of an additive (sintering aid) between a central portion and a peripheral portion of each layer, wherein a compressive stress exist in central portions of surface layers, whereas no stress exists in a central layer in the thickness direction;

FIG. 8B illustrates a case where a plurality of layers are provided in a thickness direction while differentiating at least one of type, quantity and composition of an additive (sintering aid) between a central portion and a peripheral portion of each layer, wherein a compressive stress exist in central portions of surface layers, whereas a tensile stress exists in a central portion of a central layer in the thickness direction;

FIG. 9A explains a method for generating a compressive stress by providing a tension generating element at a peripheral portion of the mounting table;

FIG. 9B illustrates a method for generating a compressive stress by providing a tension generating element at an outer circumferential portion of the mounting table; and

FIG. 10 depicts a perspective view of a wafer mounting table in accordance with another embodiment of the present invention.

### DETAILED DESCRIPTION OF THE EMBODIMENT

Hereinafter, embodiments of the present invention will be described with reference to the accompanying drawings.

Herein, there will be described an example case in which a ceramic member of the present invention is employed in a substrate mounting mechanism of a CVD film forming apparatus.

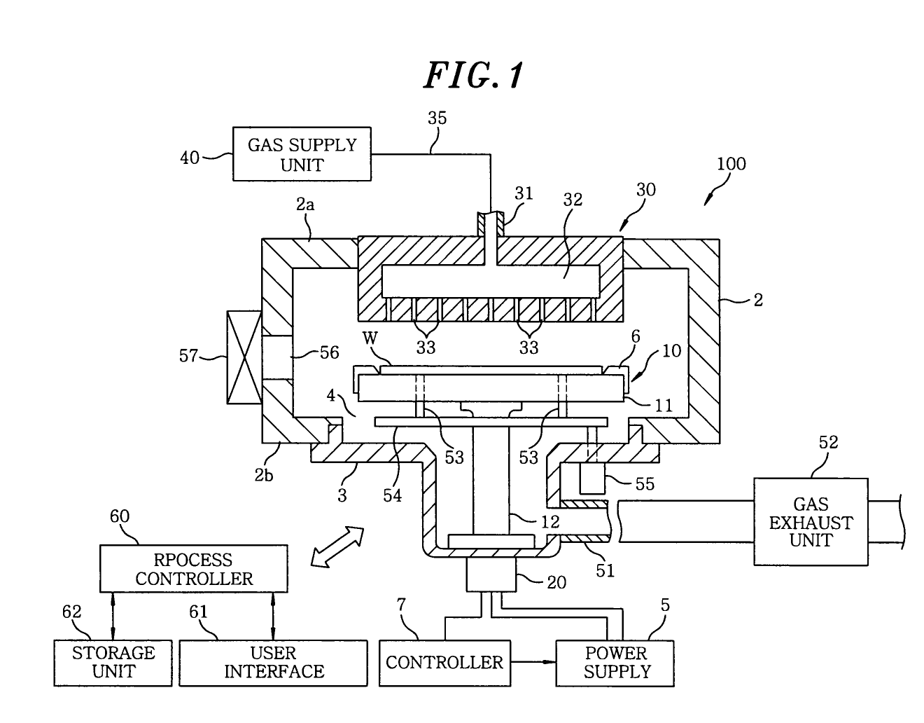

FIG. 1 is a schematic cross sectional view of a CVD film forming apparatus employing a wafer mounting mechanism in accordance with an embodiment of the present invention. The CVD film forming apparatus 100 includes a substantially cylindrical airtight chamber 2 and an exhaust chamber 3 protruded downward from a bottom wall 2b of the chamber 2. The chamber 2 and the exhaust chamber 3 form an entire processing chamber. The chamber 2 has therein a wafer mounting mechanism 10 for horizontally mounting and heating a semiconductor wafer (hereinafter, referred to as “wafer”) as a target substrate. The wafer mounting mechanism 10 includes a wafer mounting table 11; and a cylindrical supporting member 12 for supporting a central portion of the wafer mounting table 11. The wafer mounting table 11 has a base body provided with a wafer mounting surface and formed of a ceramic member, and a heating element buried in the base body. The cylindrical supporting member 12 extends upward from a bottom portion of the exhaust chamber 3 forming the processing chamber. Further, provided outside the chamber 2 is a power supply 5 for supplying power to the heating element of the wafer mounting table 11 and the like. Accordingly, the power is supplied from the power supply 5 to the heating element and the like via a connecting chamber 20. The power supply 5 is connected with a controller 7, so that a temperature of the wafer mounting table 11 and the like can be adjusted by controlling the power from the power supply 5. The control system will be described in detail later. Moreover, a guide ring 6 for guiding the wafer W is provided at an outer circumferential portion of the wafer mounting table 11.

A shower head 30 is provided on a ceiling wall 2a of the chamber 2 and connected with a gas supply unit 40. Further, the shower head 30 has a gas inlet opening 31 on the upper surface thereof, a gas diffusion space 32 therein and gas injection openings 33 on the bottom surface thereof. The gas inlet opening 31 is connected with a gas supply line 35 extending from the gas supply unit 40. Accordingly, a film forming gas is introduced to the gas inlet opening 31 from the gas supply unit 40.

The exhaust chamber 3 is protruded downward while covering a circular opening 4 formed at a central portion of the bottom wall 2b of the chamber 2. A gas exhaust line 51 is connected with a side surface of the exhaust chamber 3, and a gas exhaust unit 52 is connected with the gas exhaust line 51. By operating the gas exhaust unit 52, an inner space of the chamber 2 can be depressurized to a specific vacuum level.

Provided in the wafer mounting table 11 are three wafer supporting pins 53 for supporting and vertically moving the wafer W (only two of them are shown), the supporting pins 53 capable of protruding from and retracting into a surface of the wafer mounting table 11. Since the wafer supporting pins 53 are fixed on a supporting plate 54, they are moved up and down through the supporting plate 54 by a driving mechanism 55 such as an air cylinder or the like.

Provided on a sidewall of the chamber 2 are a loading/unloading port 56 through which the wafer is loaded into the chamber 2 from a transfer chamber held at a vacuum state (not shown) and vice versa and a gate valve 57 for opening/closing the loading/unloading port 56.

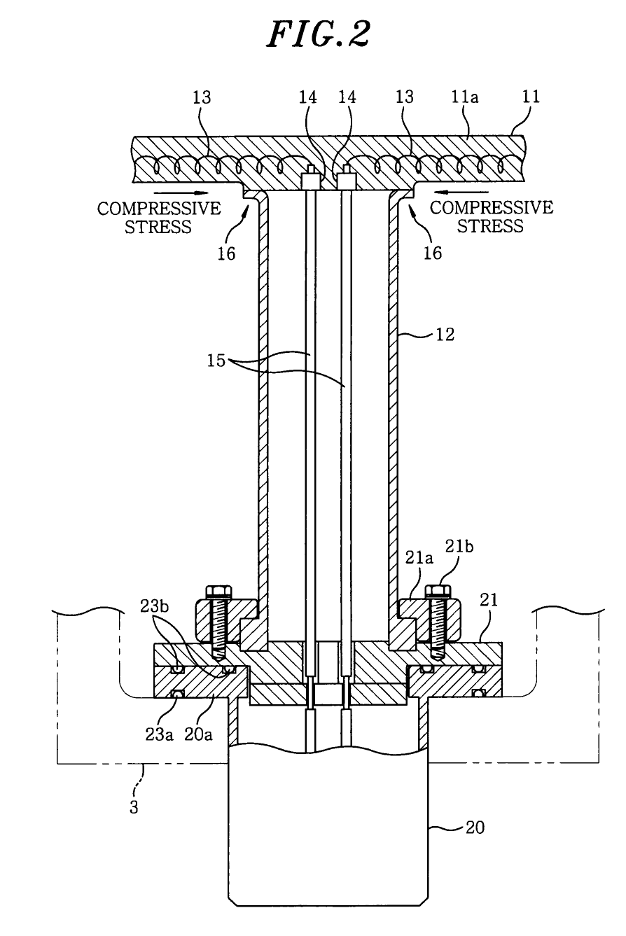

Hereinafter, the wafer mounting mechanism 10 will be described in detail with reference to FIG. 2 showing an enlarged cross sectional view thereof.

As described above, the wafer mounting mechanism 10 includes the wafer mounting table 11 and the cylindrical supporting member 12 for supporting the wafer mounting table 11. The wafer mounting table 11 configured as a ceramic heater has a base body 11a and a heating element 13 buried in the base body 11a. The base body 11a is formed of a ceramic member made of a ceramic material, e.g., AlN, Al₂O₃, SiC, SiO₂ or the like, and the heating element 13 is made of a refractory metal, e.g., W, Mo, V, Cr, Mn, Nb, Ta or the like, or a compound of such metals. The heating element 13 is divided into two parts connected with respective power feeding terminal sections 14 provided at a central portion of the wafer mounting table 11 to supply power thereto. For simplicity, FIG. 2 shows only two power feeding terminal sections 14, each of which is connected with the corresponding part of the heating element 13. However, each part of the heating element 13 is actually connected with two power feeding terminal sections 14.

The supporting member 12 as well as the wafer mounting table 11 is made of a ceramic material such as AlN, Al₂O₃, SiC, SiO₂ or the like. Further, the supporting member 12 is contacted with a central portion of a backside of the wafer mounting table 11, thereby forming a bonding section 16. Disposed inside the supporting member 12 are four power feed rods 15 extending in a vertical direction (only two of them are illustrated). The power feed rods 15 have upper ends connected with the respective power feeding terminal sections 14 and lower ends extending to an inside of the connecting chamber 20. The connecting chamber 20 is attached to a lower portion of the supporting member 12 while being protruded downward from the exhaust chamber 3. The power feed rods 15 are made of a heat resistant metallic material such as Ni alloy or the like.

A flange-shaped bottom cover 21 made of an insulating material is attached to a bottom portion of the supporting member 12 by using attaching members 21a and screws 21b. Further, through holes are vertically provided in the bottom cover 21 so that the power feed rods 15 can be extended therethrough. Further, the connecting chamber 20 is formed in a cylindrical shape and has a flange 20a at the upper end thereof. The flange 20a is interposed between the bottom cover 21 and a bottom wall of the exhaust chamber 3. A space between the flange 20a and the bottom wall of the exhaust chamber 3 is airtightly sealed by an annular sealing member 23a and, also, a space between the flange 20a and the bottom cover 21 is airtightly sealed by two annular sealing members 23b. Moreover, the power feed rods 15 are connected, inside the connecting chamber 20 with respective power feed lines (not shown) extending from the power supply 5.

The base body 11a of the wafer mounting table 11 formed of a ceramic member is connected at its central portion with the supporting member 12 and the power feed rods 15, so that the heat is likely to be lost at the central portion. As a consequence, the central portion of the base body 11a has a lower temperature compared with other portions and, thus, a tensile stress derived from a thermal expansion difference is applied thereto. Since the central portion of the base body 11a has portions that can be crack starting points in structure, e.g., the bonding section 16 of the supporting member 12, the connecting portions of the power feeding terminal sections 14 and the like, the application of the tensile stress to those portions results in a breakage of the base body 11a. To that end, in this embodiment, the base body 11a and the wafer mounting table 11 including same are formed in a state that a compressive stress is generated in the portions that are likely to be crack starting points, such as the central portion thereof.

The following is an explanation of an entire control system of the film forming apparatus 100.

Each component of the film forming apparatus 100 is connected to and controlled by a process controller 60. A user interface 61 is connected to the process controller 60, wherein the user interface 61 includes, e.g., a keyboard for a process manager to input a command to operate the film forming apparatus 100, a display for showing an operational status of the film forming apparatus 100 and the like.

Moreover, connected to the process controller 60 is a storage unit 62 for storing therein control programs for implementing various processes, which are performed in the film forming apparatus 100 under the control of the process controller 60, and programs or recipes to be used in carrying out the various processes by each component of the plasma etching apparatus in accordance with processing conditions. The recipes can be stored in a hard disk or a semiconductor memory, or can be set at a certain position of the storage unit 62 while being recorded on a portable storage medium such as a CDROM, a DVD and the like. Alternatively, the recipes can be transmitted from another apparatus via, e.g., a dedicated line.

When receiving a command from the user interface 61, the process controller 60 retrieves a necessary recipe from the storage unit 62 and a desired process is performed in the film forming apparatus 100 under the control of the process controller 60.

In the film forming apparatus 100 configured as described above, the wafer mounting table 11 is heated to, e.g., about 700° C., by supplying power from the power supply 5 to the heating element 13 buried in the wafer mounting table 11. Next, the inner space of the chamber 2 is exhausted to vacuum by the gas exhaust unit 52. By opening the gate valve 57, a wafer W is loaded from the vacuum transfer chamber (not shown) into the chamber 2 via the loading/unloading port 56 and then mounted on the top surface of the wafer mounting table 11. Thereafter, the gate valve 57 is closed. Then, a film forming gas is supplied from the gas supply unit 40 to the shower head 30 at a specific flow rate via the gas supply line 35. By supplying the film forming gas from the shower head 30 to the chamber 2, a reaction occurs on a surface of the wafer W and, thus, a specific film is formed thereon.

As described above, the base body 11a of the wafer mounting table 11 formed of a ceramic member is connected at its central portion with the supporting member 12 and the power feed rods 15. Therefore, when the wafer mounting table 11 reaches a high temperature during the film forming process, the heat is likely to be lost at the central portion through the supporting member 12 and the power feed rods 15. Accordingly, the central portion of the base body 11a has a lower temperature compared with other portions and, hence, a tensile stress derived from a thermal expansion difference is applied thereto. The application of the tensile stress to the central portion may result in a breakage of portions that can be crack starting points in structure, such as the bonding section 16 of the supporting member 12, the connecting portions of the power feeding terminal sections 14 and the like.

To that end, in this embodiment, the base body 11a and the wafer mounting table 11 including same are formed in a state that a compressive stress is generated in the portions that are likely to be crack starting points, such as the central portion thereof.

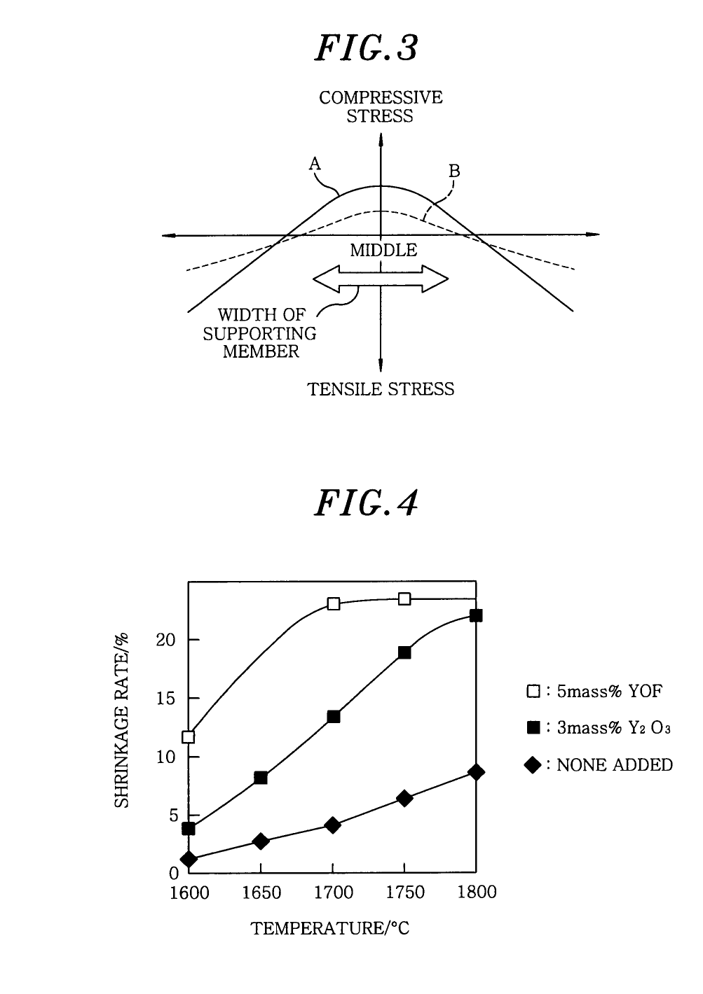

FIG. 3 depicts a stress distribution in a diametrical direction of the wafer mounting table 11. The compressive stress is generated in the central portion of the wafer mounting table 11 formed of a ceramic member in a room temperature, as indicated by a solid line A of FIG. 3. However, when the temperature of the wafer mounting table 11 increases, the central portion of the wafer mounting table 11 has a lower temperature compared with other portions due to the heat dissipation through the supporting member 12, so that the compressive stress in the central portion is reduced by the thermal expansion difference. Therefore, the compressive stress at a room temperature needs to be set high so that it can still remain, even if it is reduced at the increased temperature as indicated by a dashed line B, within a range (white arrow of FIG. 3) including the bonding section 16 of the supporting member 12 which may be crack starting points.

Since the compressive stress generated in the portions that can be crack starting points prevents a generation of cracks, no breakage occurs.

The following is a description of methods for generating a stress in the ceramic member forming the wafer mounting table 11.

A first method is that the central portion and the peripheral portion of the wafer mounting table 11 formed of the ceramic member are sintered at different temperatures. In general, ceramic sintered bodies have different shrinkage rates depending on their sintering temperatures. Therefore, the compressive stress can be generated in the central portion of a ceramic member by sintering the central portion and the peripheral portion at different temperatures.

That is, when a ceramic member is manufactured in a temperature range where the shrinkage rate increases as the sintering temperature increases, if the sintering temperature of the peripheral portion of the ceramic member is greater than that of the central portion, the shrinkage rate of the peripheral portion becomes greater than that of the central portion. As a consequence, a compressing force is applied from the peripheral portion to the central portion, thereby generating a compressive stress.

FIG. 4 shows a relationship, in case of using AlN as a ceramic material forming the base body 11a of the wafer mounting table 11, between a sintering temperature and a shrinkage rate (see “Low temperature sintering of AlN by using fluoride as a sintering aid”, http://www.ise.chuo-u.ac.jp/TISE/pub/annual07/199905oishi.pdf: Katsuyoshi Ohishi, Youichi Takahashi of Applied chemistry engineering, Chuo university). As can be seen from in FIG. 4, the increase of the sintering temperature leads to the increase of the shrinkage rate regardless of a shrinkage rate variation depending on existence/nonexistence of an additive and its type.

A linear expansion coefficient of AlN is about 5 ppm/° C. Therefore, when a difference in a temperature distribution of the base body 11a is, e.g., about 50° C., a difference in a thermal expansion coefficient is merely about 0.025%. In order to generate a stress capable of compensating such a thermal expansion coefficient difference, a difference in a shrinkage rate during a sintering process needs to be greater than about 0.025%. For example, in case no additive is added, the shrinkage rate is about 6.5%/200° C., as can be seen from FIG. 4. Therefore, a difference in the sintering temperature needs to be about 0.8° C. or greater in order to obtain the required shrinkage rate difference.

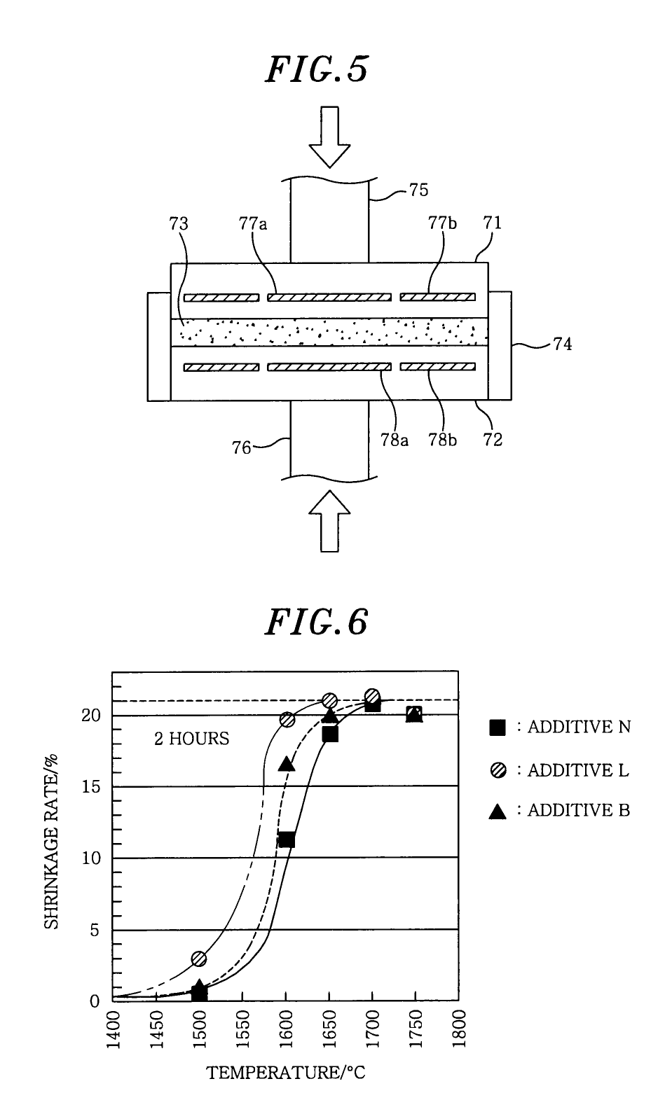

In order to differentiate a sintering temperature of the central portion from that of the peripheral portion, there can be employed a method for controlling a temperature of each portion by using, e.g., a hot pressing device. A detailed description thereof will be provided with reference to FIG. 5. FIG. 5 is a schematic diagram of the hot pressing device capable of sintering the central portion and the peripheral portion of a ceramic member at different temperatures. In the hot pressing device, an upper heater 71 and a lower heater 72 are provided to face each other in a chamber (not illustrated) and a specimen chamber 73 is formed therebetween. Further, a ring-shaped mold 74 is disposed around the specimen chamber 73 via a slight clearance between the upper heater 71 and the lower heater 72. An upper shaft 75 extends vertically upward from a central portion of the top surface of the upper heater 71, while a lower shaft 76 extends vertically downward from the bottom surface of the lower heater 72. The upper shaft 75 and the lower shaft 76 move vertically by a hydraulic cylinder (not illustrated). After inputting ceramic material powder into the specimen chamber 73, the upper and the lower heater 71 and 72 heated to a specific temperature are moved by the cylinder in the arrow directions. Accordingly, the ceramic material power is hot-pressed, thereby producing a specific-shaped sintered body.

A central heating element 77a and a peripheral heating element 77b are buried in the central portion and the peripheral portion of the upper heater 71, respectively. Moreover, a central heating element 78a and a peripheral heating element 78b are buried in the central portion and the peripheral portions of the lower heater 72, respectively. Since each temperature of the central portion and the peripheral portion can be controlled with high accuracy, a sintering temperature of the central portion can be slightly differentiated from that of the peripheral portion. The sintering temperature difference thus generated increases a shrinkage rate of the peripheral portion compared with that of the central portion. As a result, a compressive stress is generated at the central portion.

In case the ceramic material is a non-oxide ceramics, such as AlN, Si₃N₄ or the like, it is preferable to use a vacuum hot pressing device for performing a hot pressing operation while maintaining an inner space of the chamber at a vacuum state or a hot pressing device capable of controlling the inner atmosphere of the chamber. Further, it is also possible to make either one of the upper heater 71 and the lower heater 72 movable by the cylinder.

Hereinafter, a second method for generating a compressive stress will be explained.

The second method is to differentiate at least of type, quantity and composition of an additive (sintering aid) between the central portion and the peripheral portion of the base body 11a formed of a ceramic member. In general, a ceramic sintered body has different shrinkage rates depending on the type, quantity and composition of the additive (sintering aid). Therefore, the compressive stress can be generated in the central portion by intentionally differentiating at least one of the type, quantity and composition of the sintering aid between the central portion and the peripheral portion.

In other words, by adding additives (sintering aid) to the central portion and the peripheral portion for relatively decreasing and increasing the shrinkage rate at the same sintering temperature, the following relationship can be realized.

(shrinkage rate of central portion)<(shrinkage of peripheral portion)

Accordingly, a compressing force is applied from the peripheral portion to the central portion, thereby generating a compressive stress.

FIG. 6 shows a relationship, in case using AlN as a ceramic material forming the base body 11a of the wafer mounting table 11, between a sintering temperature and a shrinkage rate (cited from “Low temperature sintering of AlN by using oxide and borides as a sintering aid”, http://www.ise.chuo-u.ac.jp/TISE/pub/nenpou/200008oishi.pdf: Katsuyoshi Ohishi, Dakahashi Youichi of Applied chemistry engineering, Chuo university). As can be seen from FIG. 6, the shrinkage rate varies depending on the type and composition of an additive.

As described above, a linear expansion coefficient of AlN is about 5 ppm/° C. Therefore, when a difference in a temperature distribution of the base body 11a is, e.g., about 50° C., a difference in a thermal expansion coefficient is merely about 0.025%. In order to generate a stress capable of compensating such a thermal expansion coefficient difference, a difference in a shrinkage rate during a sintering process needs to be greater than about 0.025%. FIG. 6 depicts shrinkage rate curves of an additive N (3 mass % Y₂O₃-1 mass % CaO), an additive L (3 mass % Y₂O₃-1 mass % CaO-0.25 mass % LaB₆) and an additive B (3 mass % Y₂O₃-1 mass % CaO-0.25 mass % B₂O₃). In FIG. 6, shrinkage rate difference greater than or equal to 1% can be obtained by employing any combination among N-L, N-B and B-L. Thus, a required compressive stress can be generated in the central portion of the wafer mounting table 11.

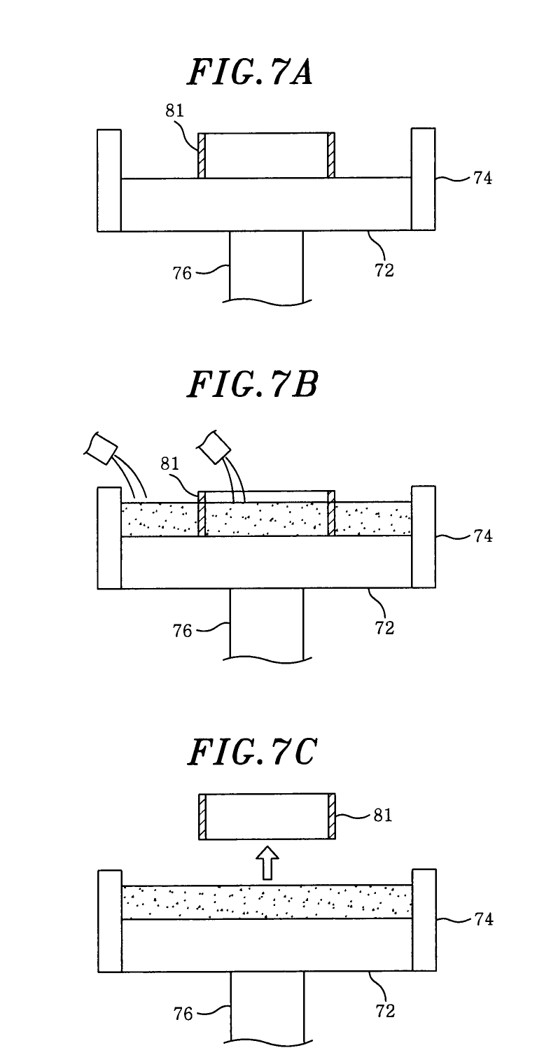

In order to differentiate at least one of the type, quantity, composition of an additive (sintering aid) between the central portion and the peripheral portion, there can be employed a method illustrated in FIGS. 7A to 7C. To be specific, in a state where the upper heater 71 is retracted upward, a ring-shaped partition member 81 is provided to partition the specimen chamber 73 into a central portion and a peripheral portion (FIG. 7A). Thereafter, different source materials are respectively input into two parts partitioned by the partition member 81 (FIG. 7B). The source materials are different in at least one of the type, quantity and composition of an additive. Then, the partition member 81 is removed (FIG. 7C). Next, the hot pressing operation is performed in the above-described sequence by using, e.g., the hot pressing device of FIG. 5, thereby obtaining a sintered body having a central portion to which a required compressive stress is applied. In this case, it is not necessary to differentiate the sintering temperature of the central portion from that of the peripheral portion. However, by sintering the central portion and the peripheral portion at different sintering temperatures, it is possible to obtain synergy effects of combining the difference in the sintering temperature and the difference in at least one of the type, quantity and composition of an additive (sintering aid).

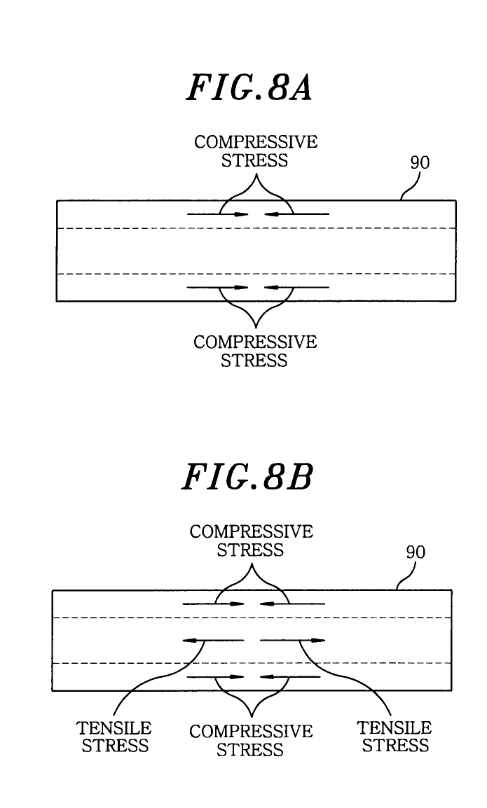

As described above, the compressive stress is generated in the central portion by differentiating at least one of the type, quantity and composition of an additive (sintering aid) between the central portion and the peripheral portion. However, a plurality of layers may be arranged in a thickness direction. In this case, at least one of the type, quantity and composition of an additive (sintering aid) may be differentiated between a central portion and a peripheral portion of each layer. For example, as shown in FIG. 8A, the compressive stress may exist exclusively in surface layers of the ceramic member 90 in case no compressive stress is needed in a central layer in the thickness direction. Further, as depicted in FIG. 8B, a tensile stress may exist in the intermediate layer.

In that case, as shown in FIG. 7B, source materials having different additives in at least one of the type, quantity and composition are respectively input into two parts partitioned by the partition member 81 up to a height corresponding to one surface layer, so that the compressive stress can exist in the central portion. Next, source materials having the same additive are input into the two parts partitioned by the partition member 81 up to a height of the intermediate layer, to thereby prevent generation of a stress in a diametrical direction. Or, source materials having different additives in at least one of the type, quantity and composition are input into the two parts partitioned by the partition member 81, so that a tensile stress can exist in the central portion. Thereafter, the initial source materials having different addictives are respectively input into the two parts partitioned by the partition member 81 up to a height corresponding to the other surface layer, so that the compressive stress can exist in the central portion.

The following is a description of a third method for generating a compressive stress.

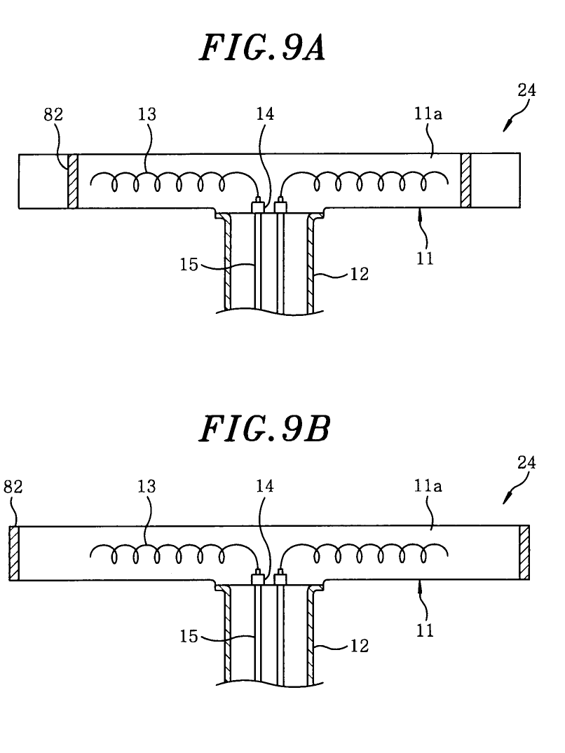

In the third method, a compressive stress is generated in the base body 11a due to a thermal expansion difference between the base body 11a and an annular tension generating element 82 provided at a peripheral portion or an outer circumferential portion of the wafer mounting table 11 (ceramic member), as shown in FIGS. 9A and 9B. Even though the case of FIG. 9B is simpler to be implemented, when the tension generating element 82 has a poor corrosion resistance, it is preferable to bury it in the wafer mounting table 11, as illustrated in FIG. 9A. To realize this, there can be employed a method for burying a metal having high plastic deformability, as the tension generating element 82, in a source material and then performing a sintering process thereon, a method including: sintering an inner portion of the wafer mounting table 11, which will be located inner side than the tension generating element 82, for a part of a whole sintering time, installing the tension generating element 82, inputting a source material into an outer portion thereof, and then sintering the entire portion or the like.

As described above, the compressive stress is generated in the central portions that are likely to be crack starting points in structure, such as the bonding section 16 of the supporting member 12, the connecting portions of the power feeding terminal sections 14 and the like. Therefore, it is possible to prevent such portions from being broken by a tensile stress applied thereto.

Although there has been described a case where the wafer mounting table 11 is configured as a ceramic heater, the method for generating a compressive stress in portions that are likely to be crack starting points can also be applied to a wafer mounting table having no heater.

An example thereof will be described hereinafter.

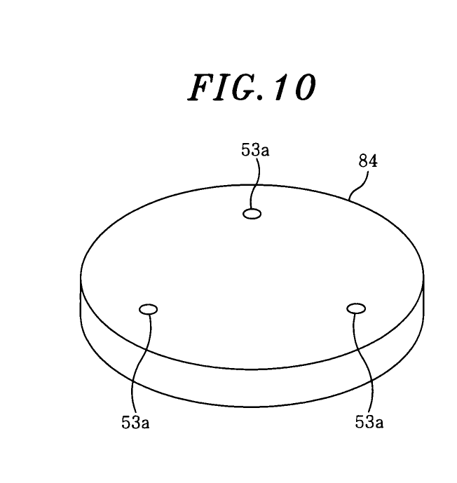

In the thermal CVD apparatus used in the aforementioned embodiments, the wafer mounting table 11 configured as a ceramic heater is required to heat a wafer as a substrate to a high temperature, e.g., about 700° C. However, in case of an apparatus for performing a process that does not require a high temperature, such as a plasma processing or the like, there can be employed a wafer mounting table 84 formed of a ceramic member having no heating element, as shown in FIG. 10. Since the wafer mounting table 84 is not heated by a heating element, a tensile stress is hardly generated in its central portion, resulting in a low possibility of breakage in the central portion. Meanwhile, through holes 53a through which where wafer supporting pins 53 are inserted have a high possibility of breakage. In other words, the through holes 53a for the wafer supporting pins 53 are formed by a boring process are and thus apt to be crack starting points. Moreover, a tensile stress can be generated at the through holes 53a, which results in a breakage thereof. To that end, a compressive stress is applied to peripheral portions of the through holes 53a for the wafer supporting pins 53, so that the above-described effects can be obtained.

In that case, as for a method for applying a compressive stress, there can be employed the first method for differentiating a sintering temperature of the central portion from that of the peripheral portion or the second method for differentiating at least one of the type, quantity and composition of an additive (sintering aid) between the central portion and the peripheral portion. In this case, however, shrinkage rates corresponding to the respective portions are set opposite to those in the above-described case as follows.

(shrinkage rate of centered portion)>shrinkage rate of peripheral portion)

The wafer mounting table having no heating element has a considerably low possibility of breakage compared with the wafer mounting table 11 configured as a ceramic heater. However, the breakage can be more positively prevented by generating a compressive stress in portions that may possibly be crack starting points due to a tensile stress applied thereto.

The present invention can be variously modified without being limited to the aforementioned embodiments. For example, in the aforementioned embodiments, the supporting member is provided at the central portion of the wafer mounting table configured as the ceramic heater. However, a plurality of supporting members may be provided at a peripheral portion of the wafer mounting table. In this case, the wafer mounting table is formed such that a compressive stress is generated in the peripheral portion thereof. Moreover, in the aforementioned embodiments, the ceramic member of the present invention is employed in the wafer mounting mechanism of the CVD film forming apparatus or in the wafer mounting mechanism having no wafer heating unit. However, it may be employed, without being limited to these wafer mounting mechanisms, in a member having portions that are likely to be crack starting points which cause breakage thereof.

### INDUSTRIAL APPLICABILITY

The ceramic member of the present invention is suitable for a substrate mounting mechanism configured as a ceramic heater in which a substrate is placed on a substrate mounting table supported by a supporting member in a chamber.

What is claimed is:

1. A ceramic member having a portion that is likely to be a crack starting point, wherein a compressive stress is generated in the portion that is likely to be the crack starting point.

2. A ceramic heater comprising:
a main body formed of a ceramic member;
a heating element buried in the main body; and
a power feeding section where power is supplied to the heating element, wherein a compressive stress is applied to the vicinity of the power feeding section of the main body.

3. A substrate mounting mechanism for mounting a substrate in a processing chamber of a substrate processing apparatus, the substrate mounting mechanism comprising:
a substrate mounting table formed of a ceramic member, for mounting thereon a substrate; and
a supporting member having one end connected to the substrate mounting table, for supporting the substrate mounting table in the processing chamber, wherein a compressive stress is applied to a section of the ceramic member to which the supporting member is connected.

4. The substrate mounting mechanism of claim 3, wherein the supporting member is provided at a central portion of the substrate mounting table.

5. A substrate mounting mechanism for mounting a substrate in a processing chamber of a substrate processing apparatus, the substrate mounting mechanism comprising:
a substrate mounting table formed of a ceramic member, for mounting thereon a substrate; and
a supporting member for supporting the substrate mounting table in the processing chamber, wherein the substrate mounting table has a plurality of through holes through which a plurality of substrate supporting pins for supporting the substrate is inserted, and a compressive stress is applied to portions where the through holes of the substrate mounting table are provided.

6. A substrate mounting mechanism for mounting and heating a substrate in a processing chamber of a substrate processing apparatus, the substrate mounting mechanism comprising:
a substrate mounting table formed of a ceramic member, for mounting thereon a substrate, the substrate mounting table having a base body and a heating element buried in the base body to heat the substrate;
a supporting member having one end connected to the substrate mounting table, for supporting the substrate mounting table in the processing chamber; and
a power feeding section where power is supplied to the heating element via power feed lines extending through the supporting member, wherein a compressive stress is generated in a section of the substrate mounting table to which the power feeding section and/or the supporting member are/is connected.

7. The substrate mounting mechanism of claim 6, wherein the supporting member is provided at a central portion of the substrate mounting table.

8. A substrate processing apparatus comprising:
a processing chamber having an inner space maintained at a depressurized state, for accommodating therein a substrate;
a substrate mounting mechanism provided in the processing chamber, for mounting the substrate; and
a processing mechanism for performing a specific processing on the substrate in the processing chamber, wherein the substrate mounting mechanism includes:
a substrate mounting table formed of a ceramic member, for mounting thereon a substrate; and
a supporting member having one end connected to the substrate mounting table, for supporting the substrate mounting table in the processing chamber, wherein a compressive stress is applied to a section of the ceramic member to which the supporting member is connected.

9. The substrate processing apparatus of claim 8, wherein the supporting member of the substrate mounting mechanism is provided at a central portion of the substrate mounting table.

10. A substrate processing apparatus comprising:
a processing chamber having an inner space maintained at a depressurized state, for accommodating therein a substrate;
a substrate mounting mechanism provided in the processing chamber, for mounting the substrate; and
a processing mechanism for performing a specific processing on the substrate in the processing chamber, wherein the substrate mounting mechanism includes:
a substrate mounting table formed of a ceramic member, for mounting thereon a substrate; and
a supporting member for supporting the substrate mounting table in the processing chamber, wherein the substrate mounting table has a plurality of through holes through which a plurality of substrate supporting pins for supporting the substrate is inserted, wherein a compressive stress is applied to portions where the through holes of the substrate mounting table are provided.

11. A substrate processing apparatus comprising:
a processing chamber having an inner space maintained at a depressurized state, for accommodating therein a substrate;
a substrate mounting mechanism provided in the processing chamber, for mounting the substrate; and
a processing mechanism for performing a specific processing on the substrate in the processing chamber, wherein the substrate mounting mechanism includes:
a substrate mounting table formed of a ceramic member, for mounting thereon a substrate, the substrate mounting table having a base body and a heating element buried in the base body to heat the substrate;
a supporting member having one end connected to the substrate mounting table, for supporting the substrate mounting table in the processing chamber; and
a power feeding section where power is supplied to the heating element via power feed lines extending through the supporting member, wherein a compressive stress is generated in a section of the substrate mounting table to which the power feeding section and/or the supporting member are/is connected.

12. The substrate processing apparatus of claim 11, wherein the supporting member of the substrate mounting mechanism is provided at a central portion of the substrate mounting table.

13. A method for manufacturing a ceramic member, comprising:
generating a compressive stress in a portion of the ceramic member that is likely to be a crack starting point during a manufacturing process of the ceramic member.

14. The method of claim 13, wherein the compressive stress is generated by sintering the portion that is likely to be a crack starting point and the other portions at different temperatures.

15. The method of claim 13, wherein the compressive stress is generated by sintering the portion that is likely to be a crack starting point and the other portions while differentiating at least one of type, quantity and composition of an additive therebetween.

16. The method of claim 13, wherein the compressive stress is generated due to a thermal expansion difference between the ceramic member and an annular tension generating element provided at a peripheral portion or an outer circumferential portion of the ceramic member.
